(19) United States
(12) Patent Application Publication
(10) Pub. No.: US 2023/0052154 A1
(43) Pub. Date: Feb. 16, 2023

(54) DISPLAY SUBSTRATE, METHOD FOR MANUFACTURING THE SAME, AND DISPLAY DEVICE

(71) Applicants: Hefei Xinsheng Optoelectronics Technology Co., Ltd., Hefei, Anhui (CN); BOE Technology Group Co., Ltd., Beijing (CN)

(72) Inventors: Ming WANG, Beijing (CN); Haitao WANG, Beijing (CN); Jun CHENG, Beijing (CN); Ce ZHAO, Beijing (CN)

(21) Appl. No.: 17/785,695

(22) PCT Filed: Sep. 13, 2021
(86) PCT No.: PCT/CN2021/117988

§ 371 Date: Jun. 15, 2022

(30) Foreign Application Priority Data
Oct. 23, 2020 (CN) 202011150238.4

(51) Int. Cl. H01L 27/32; H01L 29/786; H01L 29/66

(52) U.S. Cl. CPC H01L 27/3272; H01L 29/78633; H01L 29/66742; H01L 2227/323

(57) ABSTRACT

A display substrate, a method for manufacturing the same, and a display device are provided, belonging to the technical field of display. The display substrate includes: a base substrate; a thin film transistor on the base substrate, the thin film transistor including an active layer and a gate electrode on one side of the active layer away from the base substrate, an orthographic projection of the gate electrode on the base substrate at least partially overlapping with an orthographic projection of the active layer on the base substrate; and a conductive pattern arranged on a layer different from the gate electrode, the conductive pattern and the gate electrode being separated by an insulating layer, the orthographic projection of the gate electrode on the base substrate at least partially overlapping with an orthographic projection of the conductive pattern on the base substrate. The technical solution of the present disclosure can improve the yield of OLED display substrates.

### CROSS-REFERENCE TO RELATED APPLICATIONS

This application claims priority to Chinese Patent Application No. 202011150238.4 filed in China on Oct. 23, 2020, the entire contents of which are hereby incorporated by reference.

### TECHNICAL FIELD

The present disclosure relates to the technical field of display, and more particularly, to a display substrate, a method for manufacturing the same, and a display device.

### BACKGROUND

In an Organic Light-Emitting Diode (OLED) display substrate using a top gate thin film transistor, the distance between the active layer and the gate electrode of the thin film transistor is relatively small and is easily affected by the electrostatic discharge (ESD) of the subsequent process, resulting in electrostatic breakdown of the insulating layer between the active layer and the gate electrode, and short-circuit between the active layer and the gate electrode, which adversely affects the yield of OLED display substrates.

### SUMMARY

The technical problem to be solved by the present disclosure is to provide a display substrate, a method for manufacturing the same, and a display device, which can improve the yield of OLED display substrates.

In order to solve the above technical problem, the embodiments of the present disclosure provide the following technical solutions.

In an aspect, a display substrate is provided, including: a base substrate; a thin film transistor on the base substrate, the thin film transistor including an active layer and a gate electrode on one side of the active layer away from the base substrate, an orthographic projection of the gate electrode on the base substrate at least partially overlapping with an orthographic projection of the active layer on the base substrate; and a conductive pattern arranged on a layer different from the gate electrode, the conductive pattern and the gate electrode being separated by an insulating layer, the orthographic projection of the gate electrode on the base substrate at least partially overlapping with an orthographic projection of the conductive pattern on the base substrate.

In some embodiments, the conductive pattern is connected to the gate electrode.

In some embodiments, the display substrate further includes a gate insulating layer between the gate electrode and the active layer, the conductive pattern being located on one side of the active layer facing the base substrate; the orthographic projection of the gate electrode on the base substrate falling within an orthographic projection of the gate insulating layer on the base substrate, the conductive pattern being connected to the gate electrode through a via hole penetrating the gate insulating layer; or the orthographic projection of the gate insulating layer on the base substrate falling within the orthographic projection of the gate electrode on the base substrate.

In some embodiments, the thin film transistor is a switching thin film transistor.

In some embodiments, the display substrate further includes a driving thin film transistor and a light-shielding metal pattern located at one side of the driving thin film transistor facing the base substrate, and the conductive pattern and the light-shielding metal pattern are arranged in the same layer and made of the same material.

In some embodiments, the orthographic projection of the gate electrode on the base substrate falls within an orthographic projection of the conductive pattern on the base substrate.

An embodiment of the present disclosure further provides a display device including the display substrate described above.

An embodiment of the present disclosure further provides a method for manufacturing a display substrate, including: providing a base substrate; forming a thin film transistor on the base substrate, the thin film transistor including an active layer and a gate electrode on one side of the active layer away from the base substrate, an orthographic projection of the gate electrode on the base substrate at least partially overlapping with an orthographic projection of the active layer on the base substrate; and forming a conductive pattern arranged on a layer different from the gate electrode, the conductive pattern and the gate electrode being separated by an insulating layer, the orthographic projection of the gate electrode on the base substrate at least partially overlapping with an orthographic projection of the conductive pattern on the base substrate.

In some embodiments, the forming a conductive pattern includes: forming a conductive pattern connected to the gate electrode.

In some embodiments, the display substrate further includes a driving thin film transistor and a light-shielding metal pattern located at one side of the driving thin film transistor facing the base substrate, and the forming a conductive pattern includes: forming the light-shielding metal pattern and the conductive pattern by a same patterning process.

### BRIEF DESCRIPTION OF THE DRAWINGS

FIG. 1 is a schematic circuit diagram of an OLED display substrate;

FIG. 2 is a schematic cross-sectional view of a driving thin film transistor;

FIG. 3 is a schematic cross-sectional view of a switching thin film transistor;

FIG. 4 is a schematic cross-sectional view of a thin film transistor in accordance with an embodiment of the present disclosure;

FIGS. 5-8 are schematic cross-sectional views of a thin film transistor manufactured in accordance with an embodiment of the present disclosure; and

FIGS. 9-12 are schematic plan views of a thin film transistor manufactured in accordance with an embodiment of the present disclosure.

### REFERENCE NUMERALS

01 base substrate

02 buffer layer

03 interlayer insulating layer

05 light-shielding metal pattern

06 active layer

07 gate insulating layer

08 gate electrode

09 source electrode

10 drain electrode

11 conductive pattern

12 via hole

13 source/drain metal layer

### DETAILED DESCRIPTION

In order that the technical problems, technical solutions, and advantages to be solved by the embodiments of the present disclosure will become more apparent, a detailed description will be given below with reference to the accompanying drawings and specific embodiments.

The embodiments of the present disclosure provide a display substrate, a method for manufacturing the same, and a display device, which can improve the yield of OLED display substrates.

An embodiment of the present disclosure provides a display substrate, including: a base substrate; a thin film transistor on the base substrate, the thin film transistor including an active layer and a gate electrode on one side of the active layer away from the base substrate, an orthographic projection of the gate electrode on the base substrate at least partially overlapping with an orthographic projection of the active layer on the base substrate; and a conductive pattern arranged on a layer different from the gate electrode, the conductive pattern and the gate electrode being separated by an insulating layer, the orthographic projection of the gate electrode on the base substrate at least partially overlapping with an orthographic projection of the conductive pattern on the base substrate.

In this embodiment, with regard to the thin film transistor having a top gate structure, the conductive pattern is arranged on a layer different from the gate electrode of the thin film transistor, and the orthographic projection of the gate electrode on the base substrate at least partially overlaps with the orthographic projection of the conductive pattern on the based substrate, whereby the electrostatic charges accumulated on the gate electrode can be dispersed by the conductive pattern, so as to prevent excessive accumulation of electrostatic charges on the gate electrode, which in turn prevents electrostatic breakdown of the insulating layer between the active layer and the gate electrode as well as short-circuit between the active layer and the gate electrode, and improves the yield of OLED display substrates.

In some embodiments, the conductive pattern is connected to the gate electrode. In this way, the conductive pattern can directly conduct away the electrostatic charges accumulated on the gate electrode, so as to prevent excessive accumulation of electrostatic charges on the gate electrode, which in turn prevents electrostatic breakdown of the insulating layer between the active layer and the gate electrode as well as short-circuit between the active layer and the gate electrode, improving the yield of OLED display substrates.

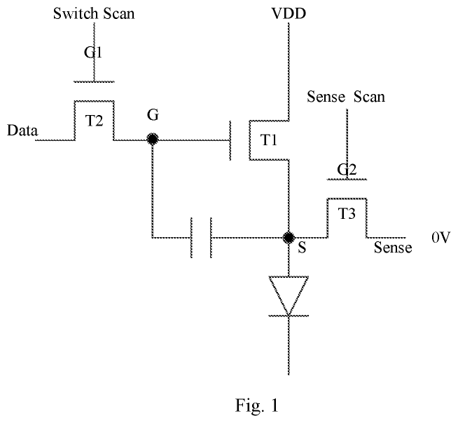

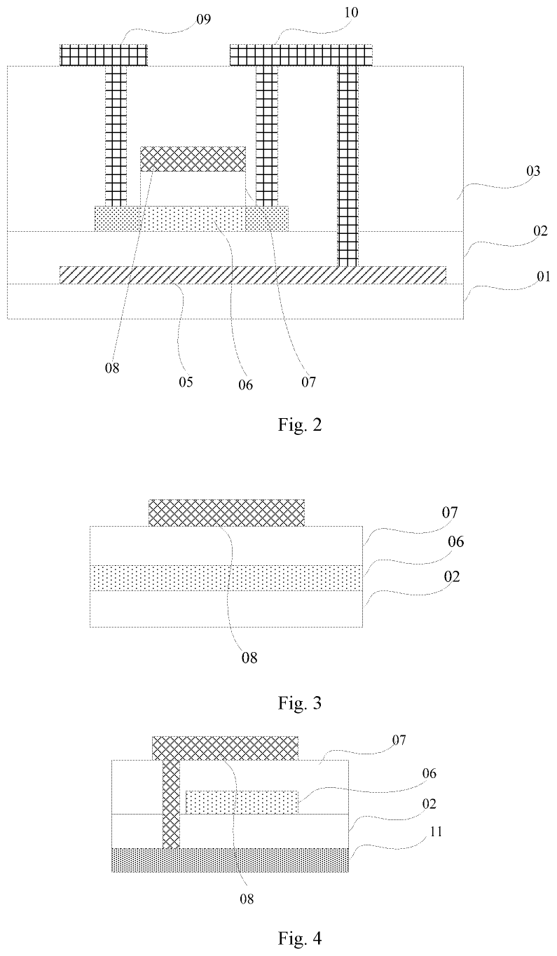

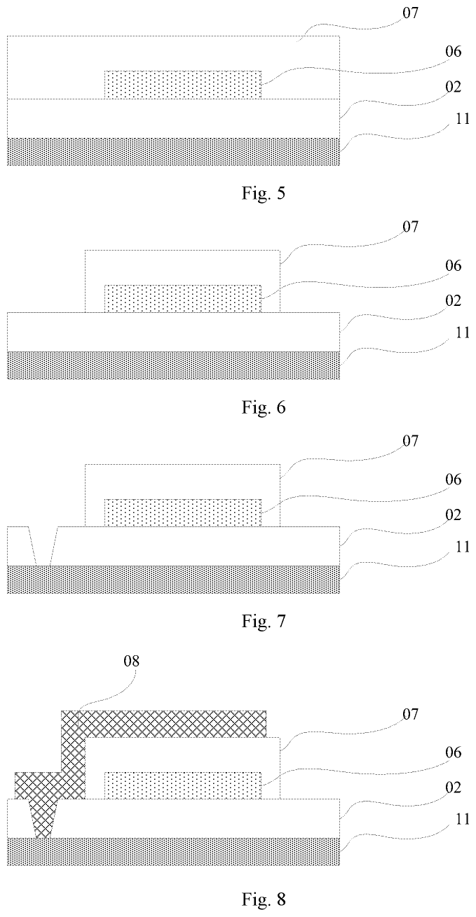

As shown in FIG. 1, an OLED display substrate includes three types of thin film transistors: T1, T2 and T3. T1 is a driving thin film transistor, and T2 and T3 are switching thin film transistors. A cross-sectional view of T1 is shown in FIG. 2, and cross-sectional views of T2 and T3 are shown in FIG. 3, in which T1 includes a light-shielding metal pattern 05, a buffer layer 02, an active layer 06, an interlayer insulating layer 03, a gate insulating layer 07, a gate electrode 08, a source electrode 09 and a drain electrode 10, which are located on a base substrate 01. As shown in FIG. 3, in T2 and T3, the active layer 06 and the gate electrode 08 are separated by the gate insulating layer 07, and the thickness of the gate insulating layer 07 is relatively small, which is generally about 1500 Angstroms. Therefore, the distance between the active layer 06 and the gate electrode 08 is relatively small, resulting in that the gate insulating layer 07 between the active layer 06 and the gate electrode 08 is easily broken down by static electricity accumulated on the gate electrode 08, and short-circuit between the active layer 06 and the gate electrode 08 occurs, affecting the yield of OLED display substrates.

As shown in FIG. 2, the light-shielding metal pattern 05 is provided in T1, and there is an overlap between the orthographic projection of the light-shielding metal pattern 05 on the base substrate and the orthographic projection of the gate electrode 08 on the base substrate, so that the light-shielding metal pattern 05 can disperse static electricity on the gate electrode 08, so as to prevent excessive accumulation of electrostatic charges on the gate electrode 08, and thus prevent electrostatic breakdown of the gate insulating layer 07 between the active layer 06 and the gate electrode 08. In this embodiment, with regard to the switching thin film transistors T2 and T3, as shown in FIG. 4 or FIG. 8, the conductive pattern 11 is provided at a position corresponding to the gate electrode 08 of the thin film transistor, and the conductive pattern 11 is connected to the gate electrode 08, so that the conductive pattern can directly conduct away the electrostatic charges accumulated on the gate electrode 08, so as to prevent excessive accumulation of electrostatic charges on the gate electrode 08, which in turn prevents electrostatic breakdown of the insulating layer between the active layer 06 and the gate electrode 08 as well as short-circuit between the active layer 06 and the gate electrode 08, improving the yield of OLED display substrates.

In some embodiments, as shown in FIG. 4, the thin film transistor includes a conductive pattern 11, a buffer layer 02, an active layer 06, a gate insulating layer 07 and a gate electrode 08 arranged in sequence. The conductive pattern 11 is located on one side of the active layer 06 facing the base substrate 01, the orthographic projection of the gate electrode 08 on the base substrate 01 falls within the orthographic projection of the gate insulating layer 07 on the base substrate 01, and the conductive pattern 11 is connected to the gate electrode 08 via a via hole penetrating the gate insulating layer 07. In this way, the conductive pattern 11 can directly conduct away the electrostatic charges accumulated on the gate electrode 08, so as to prevent excessive accumulation of electrostatic charges on the gate electrode 08, which in turn prevents electrostatic breakdown of the insulating layer between the active layer 06 and the gate electrode 08.

In other embodiments, as shown in FIG. 8, the thin film transistor includes a conductive pattern 11, a buffer layer 02, an active layer 06, a gate insulating layer 07 and a gate electrode 08, which are arranged in sequence. The conductive pattern 11 is located on one side of the active layer 06 facing the base substrate 01, the orthographic projection of the gate insulating layer 07 on the base substrate 01 falls within the orthographic projection of the gate electrode 08 on the base substrate 01, the gate electrode 08 has a portion exceeding the gate insulating layer 07, and the portion of the gate electrode 08 exceeding the gate insulating layer 07 is connected to the conductive pattern 11 via a via hole penetrating the buffer layer 02. In this way, the conductive pattern 11 can directly conduct away the electrostatic charges accumulated on the gate electrode 08, so as to prevent excessive accumulation of electrostatic charges on the gate electrode 08, which in turn prevents electrostatic breakdown of the insulating layer between the active layer 06 and the gate electrode 08.

As in the above-mentioned example, the conductive pattern 11 may be located on one side of the active layer 06 facing the base substrate 01, and furthermore, the conductive pattern 11 may also be located on one side of the active layer 06 away from the base substrate 01, as long as the conductive pattern 11 and the gate electrode 08 are arranged in different layers, and the orthographic projection of the conductive pattern 11 on the base substrate 01 and the orthographic projection of the gate electrode 08 on the base substrate 01 at least partially overlap, in which it is possible that the orthographic projection of the conductive pattern 11 on the base substrate 01 falls within the orthographic projection of the gate electrode 08 on the base substrate 01, and it is also possible that the orthographic projection of the gate electrode 08 on the base substrate 01 falls within the orthographic projection of the conductive pattern 11 on the base substrate 01, and it is also possible that the orthographic projection of the gate electrode 08 on the base substrate 01 partially overlaps with the orthographic projection of the conductive pattern 11 on the base substrate 01.

In some embodiments, the orthographic projection of the gate electrode 08 on the base substrate 01 falls within the orthographic projection of the conductive pattern 11 on the base substrate 01, namely, the area of the conductive pattern 11 exceeds the area of the gate electrode 08, so that the conductive pattern 11 can carry more electrostatic charges thereon, effectively dispersing the electrostatic charges accumulated on the gate electrode 08, and preventing excessive accumulation of electrostatic charges on the gate electrode 08.

When the conductive pattern 11 is located on the side of the active layer 06 facing the base substrate 01, the conductive pattern 11 may be arranged in the same layer and made of the same material as the light-shielding metal pattern 05, so that the conductive pattern 11 and the light-shielding metal pattern 05 may be formed simultaneously by one patterning process, the number of patterning processes for manufacturing the display substrate can be reduced, the processing time for manufacturing the display substrate can be saved, and the production cost of the display substrate can be reduced. Of course, the conductive pattern 11 may also be manufactured by a separate patterning process.

An embodiment of the present disclosure further provides a display device including the display substrate described above. The display device includes, but is not limited to: a radio frequency unit, a network module, an audio output unit, an input unit, a sensor, a display unit, a user input unit, an interface unit, a memory, a processor, a power supply, etc. It will be appreciated by those skilled in the art that the configuration of the display device described above is not intended to be limiting and that the display device may include more or fewer of the components described above, or some combinations of the components, or different arrangements of the components. In embodiments of the present disclosure, the display device includes, but is not limited to, a display, a cell phone, a tablet, a television, a wearable electronic device, a navigation display device, etc.

The display device may be: any product or component with a display function, such as a television, a display, a digital photo frame, a mobile phone, a tablet computer, and among others, the display device further includes a flexible circuit board, a printed circuit board and a back plane.

An embodiment of the present disclosure further provides a method for manufacturing a display substrate, including the following steps: a base substrate is provided; a thin film transistor is formed on the base substrate, the thin film transistor including an active layer and a gate electrode on one side of the active layer away from the base substrate, an orthographic projection of the gate electrode on the base substrate at least partially overlapping with an orthographic projection of the active layer on the base substrate; and a conductive pattern arranged on a layer different from the gate electrode is formed, the conductive pattern and the gate electrode being separated by an insulating layer, the orthographic projection of the gate electrode on the base substrate at least partially overlapping with an orthographic projection of the conductive pattern on the base substrate.

In this embodiment, with regard to the thin film transistor of top gate structure, the conductive pattern is arranged on a layer different from the gate electrode of the thin film transistor, and the orthographic projection of the gate electrode on the base substrate at least partially overlaps with the orthographic projection of the conductive pattern on the based substrate, whereby the electrostatic charges accumulated on the gate electrode can be dispersed by the conductive pattern, so as to prevent excessive accumulation of electrostatic charges on the gate electrode, which in turn prevents electrostatic breakdown of the insulating layer between the active layer and the gate electrode as well as short-circuit between the active layer and the gate electrode, and improves the yield of OLED display substrates.

In some embodiments, the forming a conductive pattern includes: a conductive pattern connected to the gate electrode is formed. In this way, the conductive pattern can directly conduct away the electrostatic charges accumulated on the gate electrode, so as to prevent excessive accumulation of electrostatic charges on the gate electrode, which in turn prevents electrostatic breakdown of the insulating layer between the active layer and the gate electrode and short-circuit between the active layer and the gate electrode, improving the yield of OLED display substrates.

As shown in FIG. 1, an OLED display substrate includes three types of thin film transistors: T1, T2 and T3. T1 is a driving thin film transistor, and T2 and T3 are switching thin film transistors. A cross-sectional view of T1 is shown in FIG. 2, and cross-sectional views of T2 and T3 are shown in FIG. 3, in which T1 includes a light-shielding metal pattern 05, a buffer layer 02, an active layer 06, an interlayer insulating layer 03, a gate insulating layer 07, a gate electrode 08, a source electrode 09 and a drain electrode 10 which are located on a base substrate 01. As shown in FIG. 3, in T2 and T3, the active layer 06 and the gate electrode 08 are separated by the gate insulating layer 07, and the thickness of the gate insulating layer 07 is relatively small, which is generally about 1500 Angstroms. Therefore, the distance between the active layer 06 and the gate electrode 08 is relatively small, resulting in that the gate insulating layer 07 between the active layer 06 and the gate electrode 08 is easily broken down by static electricity accumulated on the gate electrode 08, and short-circuit between the active layer 06 and the gate electrode 08 occurs, affecting the yield of OLED display substrates.

As shown in FIG. 2, the light-shielding metal pattern 05 is provided in T1, and there is an overlap between the orthographic projection of the light-shielding metal pattern 05 on the base substrate and the orthographic projection of the gate electrode 08 on the base substrate, so that the light-shielding metal pattern 05 can disperse static electricity on the gate electrode 08, so as to prevent excessive accumulation of electrostatic charges on the gate electrode 08, and thus prevent electrostatic breakdown of the gate insulating layer 07 between the active layer 06 and the gate electrode 08. In this embodiment, with regard to the switching thin film transistors T2 and T3, as shown in FIG. 4 or FIG. 8, the conductive pattern 11 is provided at a position corresponding to the gate electrode 08 of the thin film transistor, and the conductive pattern 11 is connected to the gate electrode 08, so that the conductive pattern can directly conduct away the electrostatic charges accumulated on the gate electrode 08, so as to prevent excessive accumulation of electrostatic charges on the gate electrode 08, which in turn prevents electrostatic breakdown of the insulating layer between the active layer 06 and the gate electrode 08 as well as short-circuit between the active layer 06 and the gate electrode 08, improving the yield of OLED display substrates.

In some embodiments, a method for manufacturing a thin film transistor includes: a conductive pattern 11, a buffer layer 02, an active layer 06, a gate insulating layer 07 and a gate electrode 08 are formed in sequence to obtain the thin film transistor as shown in FIG. 4. The conductive pattern 11 is located on one side of the active layer 06 facing the base substrate 01, the orthographic projection of the gate electrode 08 on the base substrate 01 falls within the orthographic projection of the gate insulating layer 07 on the base substrate 01, and the conductive pattern 11 is connected to the gate electrode 08 via a via hole penetrating the gate insulating layer 07. In this way, the conductive pattern 11 can directly conduct away the electrostatic charges accumulated on the gate electrode 08, so as to prevent excessive accumulation of electrostatic charges on the gate electrode 08, which in turn prevents electrostatic breakdown of the insulating layer between the active layer 06 and the gate electrode 08.

In this embodiment, when manufacturing the thin film transistor as shown in FIG. 4, a via hole is formed through the gate insulating layer 07 and the buffer layer 02 by dry etching to connect the gate electrode 08 to the conductive pattern 11, so that breakdown of the gate insulating layer 07 caused by ESD can be effectively prevented.

In other embodiments, a method for manufacturing a thin film transistor includes the following steps: a conductive pattern 11, a buffer layer 02 and an active layer 06 are formed; a gate insulating layer 07 covering the active layer 06 is formed; then as shown in FIG. 6, dry etching is performed on the gate insulating layer 07 to expose a part of the buffer layer 02 with the gate insulating layer 07 still covering the active layer 06; then, as shown in FIG. 7, dry etching is performed on the buffer layer 02 to form a via hole exposing the conductive pattern 11; then, as shown in FIG. 8, a gate metal layer is formed and the gate metal layer is patterned to form a gate electrode 08, and the gate electrode 08 is connected to the conductive pattern 11 through a via hole penetrating the buffer layer 02. In this way, the breakdown of the gate insulating layer 07 caused by ESD can be effectively prevented.

As shown in FIG. 8, in the manufactured thin film transistor, the conductive pattern 11 is located on one side of the active layer 06 facing the base substrate 01, the orthographic projection of the gate insulating layer 07 on the base substrate 01 falls within the orthographic projection of the gate electrode 08 on the base substrate 01, the gate electrode 08 has a portion exceeding the gate insulating layer 07, and the portion of the gate electrode 08 exceeding the gate insulating layer 07 is connected to the conductive pattern 11 via a via hole penetrating the buffer layer 02. In this way, the conductive pattern 11 can directly conduct away the electrostatic charges accumulated on the gate electrode 08, so as to prevent excessive accumulation of electrostatic charges on the gate electrode 08, which in turn prevents electrostatic breakdown of the insulating layer between the active layer 06 and the gate electrode 08 as well as short-circuit between the active layer 06 and the gate electrode 08, improving the yield of OLED display substrates.

As in the above-mentioned example, the conductive pattern 11 may be located on one side of the active layer 06 facing the base substrate 01, and furthermore, the conductive pattern 11 may also be located on one side of the active layer 06 away from the base substrate 01, as long as the conductive pattern 11 and the gate electrode 08 are arranged in different layers, and the orthographic projection of the conductive pattern 11 on the base substrate 01 and the orthographic projection of the gate electrode 08 on the base substrate 01 at least partially overlap, in which it is possible that the orthographic projection of the conductive pattern 11 on the base substrate 01 falls within the orthographic projection of the gate electrode 08 on the base substrate 01, and it is also possible that the orthographic projection of the gate electrode 08 on the base substrate 01 falls within the orthographic projection of the conductive pattern 11 on the base substrate 01, and it is also possible that the orthographic projection of the gate electrode 08 on the base substrate 01 partially overlaps with the orthographic projection of the conductive pattern 11 on the base substrate 01.

When the conductive pattern 11 is located on the side of the active layer 06 facing the base substrate 01, the conductive pattern 11 may be arranged in the same layer and made of the same material as the light-shielding metal pattern 05, and the forming a conductive pattern includes: the light-shielding metal pattern and the conductive pattern are formed by a same patterning process. In this way, the number of patterning processes for manufacturing the display substrate can be reduced, the process time for manufacturing the display substrate can be saved, and the production cost of the display substrate can be reduced. Of course, the conductive pattern 11 may also be manufactured by a separate patterning process.

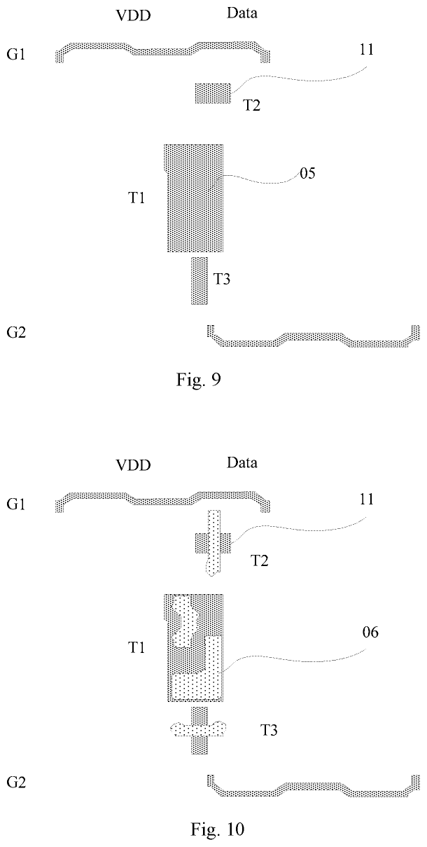

In a particular embodiment, the conductive pattern 11 is arranged in the same layer and made of the same material as the light-shielding metal pattern 05. As shown in FIGS. 9-12, a method for manufacturing a thin film transistor includes the following steps:

at step 1, as shown in FIG. 9, a metal layer is formed, and the metal layer is patterned to form a light-shielding metal pattern 05 located in the region of the thin film transistor T1 and a conductive pattern 11 located in the region where the thin film transistors T2 and T3 are located;

at step 2, a buffer layer is formed covering the light-shielding metal pattern 05 and the conductive pattern 11;

at step 3, as shown in FIG. 10, a layer of semiconductor material is formed, and the semiconductor material is patterned to form an active layer 06, the active layer 06 being distributed in regions where the thin film transistors T1, T2 and T3 are located; where the semiconductor material may be IGZO;

at step 4, a gate insulating layer is formed covering the active layer 06;

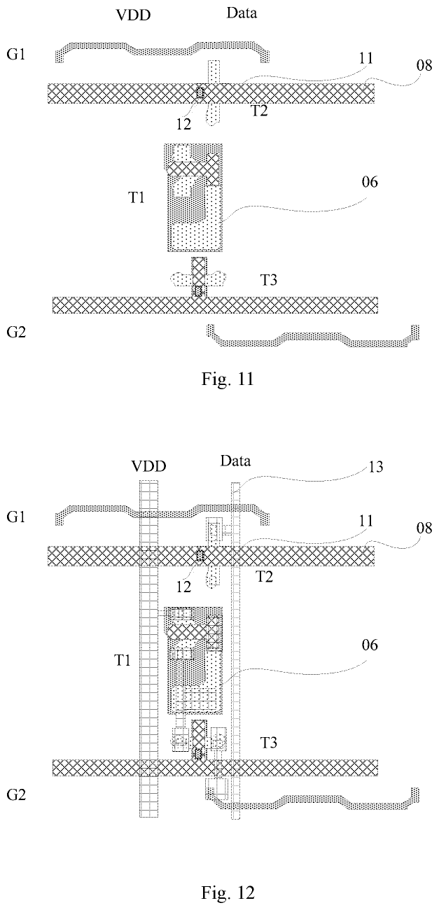

at step 5, as shown in FIG. 11, a gate metal layer is formed, the and gate metal layer is patterned to form a gate electrode 08, in the region where the thin film transistors T2 and T3 are located, the gate electrode 08 being connected to the conductive pattern 11 via a via hole 12;

at step 6, an interlayer insulating layer is formed covering the gate electrode 08; and

at step 7, as shown in FIG. 12, a source/drain metal layer 13 is formed, and the source/drain metal layer 13 is patterned to form a source electrode, a drain electrode and a data line.

The switching thin film transistors (T2 and T3) and the driving thin film transistor (T1) of the display substrate can be manufactured through the above-mentioned steps.

In this embodiment, with regard to the switching thin film transistor, the gate electrode 08 is connected to the conductive pattern 11 via the via hole, so that the ESD-type Short does not occur between the active layer 06 of the switching thin film transistor and the gate electrode 08, thereby effectively improving the yield of OLED display substrates.

In the various method embodiments of the present disclosure, the serial number of each step cannot be used to define the order of each step, and for a person of ordinary skill in the art, without involving any inventive effort, changes in the order of each step are also within the scope of the present disclosure.

It should be noted that the various embodiments described herein are described in a progressive manner with reference to the same or similar parts throughout the various embodiments, with each embodiment focusing on differences from the other embodiments. In particular, the embodiments are described more simply because they are substantially similar to the product embodiments, with reference to the partial description of the product embodiments.

Unless defined otherwise, technical or scientific terms used in this disclosure shall have the ordinary meaning as understood by one of ordinary skill in the art to which this disclosure belongs. The terms “first”, “second”, and the like as use herein do not denote any order, quantity, or importance, but rather are used to distinguish one element from another. The terms “comprising” or “comprises”, and the like, means that the presence of an element or item preceding the word covers the presence of the element or item listed after the word and equivalents thereof, but does not exclude other elements or items. The terms “connecting” or “connected” and the like are not limited to physical or mechanical connections, but may include electrical connections, whether direct or indirect. The terms “upper”, “lower”, “left”, “right” and the like are used only to indicate relative positional relationships that may change accordingly when the absolute position of the object being described changes.

It will be understood that when an element such as a layer, film, region or substrate is referred to as being “on” or “under” another element, it can be “directly on” or “directly under” the other element or intervening elements may be present.

In the description of the embodiments above, particular features, structures, materials, or characteristics may be combined in any suitable manner in any one or more embodiments or examples.

While the present disclosure has been described with reference to specific embodiments thereof, it will be understood by those skilled in the art that various changes may be made and equivalents may be substituted for elements thereof without departing from the scope of the disclosure. Accordingly, the protection sought herein is as set forth in the claims below.

1. A display substrate, comprising:
a base substrate;
a thin film transistor on the base substrate, the thin film transistor comprising an active layer and a gate electrode on one side of the active layer away from the base substrate, an orthographic projection of the gate electrode on the base substrate at least partially overlapping with an orthographic projection of the active layer on the base substrate; and
a conductive pattern arranged on a layer different from the gate electrode, the conductive pattern and the gate electrode being separated by an insulating layer, the orthographic projection of the gate electrode on the base substrate at least partially overlapping with an orthographic projection of the conductive pattern on the base substrate.

2. The display substrate according to claim 1, wherein the conductive pattern is connected to the gate electrode.

3. The display substrate according to claim 2, further comprising a gate insulating layer between the gate electrode and the active layer, the conductive pattern being located on one side of the active layer facing the base substrate;
the orthographic projection of the gate electrode on the base substrate falling within an orthographic projection of the gate insulating layer on the base substrate, the conductive pattern being connected to the gate electrode through a via hole penetrating the gate insulating layer; or
the orthographic projection of the gate insulating layer on the base substrate falling within the orthographic projection of the gate electrode on the base substrate.

4. The display substrate according to claim 1, wherein the thin film transistor is a switching thin film transistor.

5. The display substrate according to claim 4, wherein the display substrate further comprises a driving thin film transistor and a light-shielding metal pattern located at one side of the driving thin film transistor facing the base substrate, and the conductive pattern and the light-shielding metal pattern are arranged in the same layer and made of the same material.

6. The display substrate according to claim 1, wherein the orthographic projection of the gate electrode on the base substrate falls within an orthographic projection of the conductive pattern on the base substrate.

7. A display device, comprising a display substrate,
the display substrate comprising:
a base substrate;
a thin film transistor on the base substrate, the thin film transistor comprising an active layer and a gate electrode on one side of the active layer away from the base substrate, an orthographic projection of the gate electrode on the base substrate at least partially overlapping with an orthographic projection of the active layer on the base substrate; and
a conductive pattern arranged on a layer different from the gate electrode, the conductive pattern and the gate electrode being separated by an insulating layer, the orthographic projection of the gate electrode on the base substrate at least partially overlapping with an orthographic projection of the conductive pattern on the base substrate.

8. A method for manufacturing a display substrate, the method comprising:
providing a base substrate;
forming a thin film transistor on the base substrate, the thin film transistor comprising an active layer and a gate electrode on one side of the active layer away from the base substrate, an orthographic projection of the gate electrode on the base substrate at least partially overlapping with an orthographic projection of the active layer on the base substrate; and
forming a conductive pattern arranged on a layer different from the gate electrode, the conductive pattern and the gate electrode being separated by an insulating layer, the orthographic projection of the gate electrode on the base substrate at least partially overlapping with an orthographic projection of the conductive pattern on the base substrate.

9. The method according to claim 8, wherein the forming a conductive pattern comprises:
forming a conductive pattern connected to the gate electrode.

10. The method according to claim 8, wherein the display substrate further comprises a driving thin film transistor and a light-shielding metal pattern located at one side of the driving thin film transistor facing the base substrate, and the forming a conductive pattern comprises:
forming the light-shielding metal pattern and the conductive pattern by a same patterning process.

11. The display substrate according to claim 1, wherein the display substrate is an Organic Light-Emitting Diode (OLED) display substrate using a top gate thin film transistor.

12. The display substrate according to claim 3, wherein a thickness of the gate insulating layer is about 1500 Angstroms.

13. The display device according to claim 7, wherein the conductive pattern is connected to the gate electrode.

14. The display device according to claim 13, wherein the display substrate further comprises a gate insulating layer between the gate electrode and the active layer, the conductive pattern being located on one side of the active layer facing the base substrate;
the orthographic projection of the gate electrode on the base substrate falling within an orthographic projection of the gate insulating layer on the base substrate, the conductive pattern being connected to the gate electrode through a via hole penetrating the gate insulating layer; or
the orthographic projection of the gate insulating layer on the base substrate falling within the orthographic projection of the gate electrode on the base substrate.

15. The display device according to claim 7, wherein the thin film transistor is a switching thin film transistor.

16. The display device according to claim 15, wherein the display substrate further comprises a driving thin film transistor and a light-shielding metal pattern located at one side of the driving thin film transistor facing the base substrate, and the conductive pattern and the light-shielding metal pattern are arranged in the same layer and made of the same material.

17. The display device according to claim 7, wherein the orthographic projection of the gate electrode on the base substrate falls within an orthographic projection of the conductive pattern on the base substrate.

18. The display device according to claim 7, wherein the display substrate is an Organic Light-Emitting Diode (OLED) display substrate using a top gate thin film transistor.

19. The display device according to claim 14, wherein a thickness of the gate insulating layer is about 1500 Angstroms.

20. The method according to claim 8, wherein the display substrate further comprises a driving thin film transistor and a light-shielding metal pattern located at one side of the driving thin film transistor facing the base substrate, and the forming a conductive pattern comprises:
forming the light-shielding metal pattern and the conductive pattern by separate patterning processes.
